(19) United States
(12) Patent Application Publication
(10) Pub. No.: US 2026/0157127 A1
(43) Pub. Date: Jun. 4, 2026

(54) METHODS OF FORMING A STRUCTURE INCLUDING A METAL HARDMASK

(71) Applicant: ASM IP Holding B.V., Almere (NL)

(72) Inventors: Mathieu Patrice Diers, Tokyo (JP); Hideaki Fukuda, Tokyo (JP); Kai Okabe, Kawasaki-shi (JP); Sivaranjani Arumugam, Tokyo (JP); Miguel Sérgio De Abreu Neto, Tokyo (JP)

(21) Appl. No.: 19/401,844

(22) Filed: Nov. 26, 2025

Related U.S. Application Data
(60) Provisional application No. 63/726,362, filed on Nov. 29, 2024.

(51) Int. Cl. H10P 14/60; C23C 16/32; C23C 16/34; C23C 16/36; C23C 16/455; G03F 1/22

(52) U.S. Cl. CPC H10P 14/668; C23C 16/32; C23C 16/34; C23C 16/36; C23C 16/45531; C23C 16/45542; C23C 16/45553; G03F 1/22; H10P 14/6339; H10P 14/6906; H10P 14/6947; H10P 50/73; H10W 20/056

(57) ABSTRACT

Methods of forming and using a structure that includes a metal hardmask layer are disclosed. The metal hardmask can include desired properties, such as relatively high tensile strength, even after subsequent etch steps. Exemplary methods include using a cyclical deposition process to deposit the metal hardmask layer. The metal hardmask layer can include, for example, one or more of a metal nitride, a metal carbide, and a metal carbonitride.

### CROSS-REFERENCE TO RELATED APPLICATIONS

This application claims priority to U.S. Provisional Patent Application Ser. No. 63/726,362, filed Nov. 29, 2024, and titled METHODS OF FORMING A STRUCTURE INCLUDING A METAL HARDMASK, the disclosure of which is hereby incorporated by reference in its entirety.

### FIELD

The present disclosure generally relates to methods suitable for use in the formation of electronic devices. More particularly, the present disclosure generally relates to methods of forming structures that include a hardmask.

### BACKGROUND

During the manufacture of electronic devices, fine patterns of features can be formed on a surface of a substrate by patterning the surface of the substrate and removing material from the substrate surface using, for example, wet etch and/or dry etch processes. Photoresist is often used for such patterning of a surface of a substrate.

A photoresist pattern can be formed by coating a layer of photoresist onto a surface of the substrate, masking the surface of the photoresist, exposing the unmasked portions of the photoresist to radiation, such as ultraviolet light or an electron beam, and removing a portion (e.g., the unmasked or masked portion) of the photoresist, while leaving a portion (e.g., the other of the unmasked or masked portion) of the photoresist on the substrate surface. Once the photoresist is patterned, the patterned photoresist can be used as a template for etching material on the substrate surface in regions in which the photoresist was removed to form a transferred pattern in a layer underlying the photoresist. After etching, remaining photoresist can be removed.

In some cases, it may be desirable to use a hardmask to facilitate pattern transfer to underlying layers on the substrate. Use of hardmasks for feature patterning may be particularly desirable for relatively high aspect ratio features. Use of hardmasks can mitigate exposure of material layers on a substrate to a plasma process that is used to remove photoresist and can thus reduce defects in features formed by photolithography techniques. Use of hardmasks can also provide desired etch selectivity between the hardmask and the underlying layer(s) to be etched.

Use of some hardmask materials can result in undesired line wiggling and/or line edge roughness during formation of patterned features. Accordingly, improved methods of forming structures that include a hardmask are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to methods for forming a structure that includes a metal hardmask layer. The metal hardmask layer can be used to transfer a pattern to one or more underlying layers. As set forth in more detail below, exemplary hardmasks described herein can be used to form features or patterns having relatively high aspect ratios (e.g., aspect ratios greater than 20:1) with relatively little line wiggle and/or relatively low line edge roughness.

In accordance with embodiments of the disclosure, a method for forming a structure including a metal hardmask is provided. The method includes providing a substrate in a reactor and forming a metal hardmask layer on a substrate. The step of forming the metal hardmask can include repeating a cycle comprising: supplying a metal-containing precursor to the substrate, supplying a reactant to the substrate, and applying a power to the reactor to activate the reactant to react with the metal-containing precursor or derivative thereof on the substrate to form the metal hardmask. The hardmask can be or include one or more of a metal nitride, a metal carbide, and a metal carbonitride. In accordance with examples of these embodiments, the metal-containing precursor includes one or more of a molybdenum and a tungsten.

Additionally or alternatively, the metal-containing precursor comprises a compound having one or more ═NR groups, where each R is independently selected from a C2-C6 linear or branched alkane. Additionally or alternatively, the metal containing precursor can be or include a compound having one or more-NRx groups, where each R is independently selected from a C1-C4 linear or branched alkane and where x is from 1 to 3. In some cases, the method includes providing two or more metal-containing precursors to the substrate. The reactant can be or include one or more of argon, hydrogen, and/or nitrogen. In accordance with aspects of these embodiments, various parameters, such as temperature, pressure, plasma power, time, and the like, can be tuned to obtain a desired tensile stress of the deposited hardmask layer. Depositing a hardmask layer with desired tensile stress can mitigate line wiggling and/or line edge roughness that can otherwise occur after a subsequent etch process.

In accordance with additional embodiments of the disclosure, a method of forming a layer stack on a substrate is provided. An exemplary method includes providing a substrate in a reactor, forming an etch stop layer on the substrate, forming a low-k layer on the etch stop layer, forming an oxide capping layer on the low-k layer, forming a metal hardmask layer on the oxide capping layer, and forming a mask layer. In accordance with examples of these embodiments, the metal hardmask layer includes one or more of a metal nitride, a metal carbide, and a metal carbonitride. The method can further include etching a portion of the layer stack to form a recess therein, and filling the recess with a conductive material, such as copper metal.

For purposes of summarizing the invention and the advantages achieved over the prior art, certain objects and advantages of the invention may have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

A more complete understanding of the embodiments of the present disclosure may be derived by referring to the detailed description and claims when considered in connection with the following illustrative figures.

FIG. 1 illustrates a method of forming a structure in accordance with one or more embodiments of the disclosure.

FIG. 2 illustrates a timing sequence in accordance with one or more embodiments of the disclosure.

FIG. 3 illustrates a structure in accordance with one or more embodiments of the disclosure.

FIG. 4 illustrates another method in accordance with one or more embodiments of the disclosure.

FIGS. 5-9 illustrate structures in accordance with one or more embodiments of the disclosure.

FIG. 10 illustrates a transmission electron microscopy image of a hardmask layer in accordance with one or more embodiments of the disclosure.

FIG. 11 illustrates as-deposited and post-etch hardmask layer thickness in accordance with one or more embodiments of the disclosure.

FIG. 12 illustrates as-deposited and post-etch hardmask layer stress in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

In this disclosure, a gas can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gases. Exemplary seal gases include noble gases, nitrogen, and the like. In some cases, the term precursor can refer to a compound that participates in the chemical reaction that produces another compound, and particularly to a compound that constitutes a film matrix or a main skeleton of a film; the term reactant can be used interchangeably with the term precursor.

As used herein, the term substrate can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. The substrate may be continuous or non-continuous; rigid or flexible; solid or porous. The substrate may be in any form, such as a plate or a workpiece. Substrates in the form of a plate may include wafers in various shapes and sizes. A continuous substrate may extend beyond the bounds of a process chamber where a deposition process occurs and may move through the process chamber, such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material or a bundle of continuous filaments or fibers (i.e., ceramic fibers or polymer fibers). Continuous substrates may also comprise carriers or sheets upon which non-continuous substrates are mounted.

As used herein, the term film and/or layer can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g., subdivided, and may be comprised in a plurality of semiconductor devices. A film or layer may be selectively grown on some parts of a substrate, and not on others.

The term cyclic deposition process or cyclical deposition process can refer to the sequential introduction of precursors (and/or reactants) and/or plasma power into or to a reaction chamber to deposit a layer over a substrate and includes processing techniques, such as atomic layer deposition (ALD), cyclical chemical vapor deposition (cyclical CVD), hybrid cyclical deposition processes that include an ALD component and a cyclical CVD component, and plasma-enhanced ALD, CVD, and hybrid cyclical processes. In some cases, one or more reactants and/or precursors are continuously provided to the reaction chamber and a plasma power can be pulsed.

The term atomic layer deposition can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally, or alternatively, exposing the substrate to a precursor can comprise moving the substrate to a location in a substrate processing system in which the reactant or precursor is present.

As used herein, a structure can be or include a substrate as described herein. Structures can include one or more layers overlying or within the substrate, such as one or more layers formed according to a method as described herein. Full devices or partial device portions can be included within or on structures.

A number of example materials are given throughout the embodiments of the current disclosure. It should be noted that the chemical formulas given for each of the example materials should not be construed as limiting and that the non-limiting example materials given should not be limited by a given example stoichiometry.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like in some embodiments. Further, in this disclosure, the terms “including,” “constituted by” and “having” and related words can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages. The term about can mean+/−20, 10, 5, 2, 1, or 0.5% of a stated dimension, direction, shape, value or the like.

In the specification, it will be understood that the term on or over may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Similarly, it will be understood that the terms under, underlying, or below will be construed to be relative concepts.

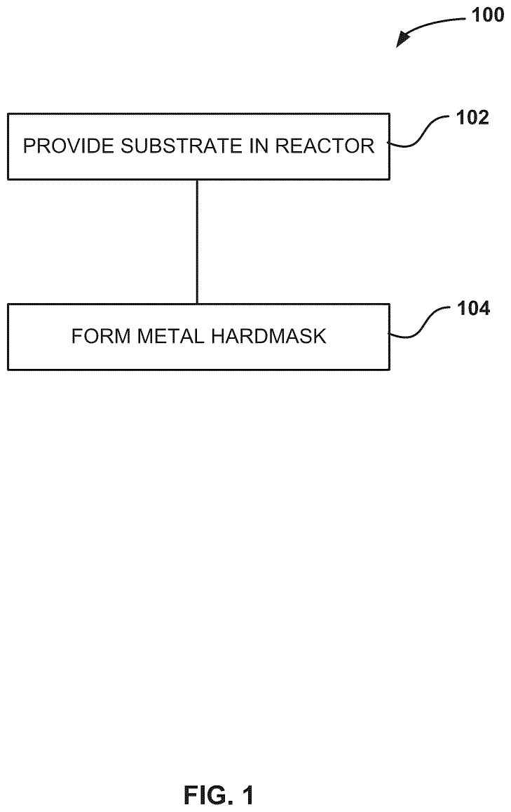

Turning to the figures, FIG. 1 illustrates an exemplary method 100 of forming a structure comprising a metal hardmask layer. In brief, method 100 includes providing a substrate in a reactor (step 102) and forming a metal hardmask layer on the substrate (step 104). Method 100 can be suitable for use in a variety of applications, particularly during formation of electronic devices. For example, method 100 may be used in back end of line (BEOL) processing of electronic devices. Additionally or alternatively, exemplary methods described herein can be used to etch high aspect ratio features with good reliability and relatively low defects. The hardmask materials described herein can also be etched away with relative ease (a vapor pressure can be less than a vapor pressure of TiN), while mitigating damage to underlying layers. Thereby allowing a relatively smooth pattern transfer.

During step 102, a substrate is provided within a reaction chamber. As noted above, the substrate can be of various forms and can include a bulk material and one or more layers and/or features formed within and/or overlying the bulk material. The reaction chamber used during step 102 can be or include a reaction chamber of a vapor deposition reactor system configured to perform a cyclical deposition process. The reaction chamber can be a standalone reaction chamber or part of a cluster tool.

Step 102 can include heating the substrate to a desired deposition temperature within the reaction chamber. In some embodiments of the disclosure, step 102 includes heating the substrate to a temperature of less than 500° C. For example, in some embodiments of the disclosure, heating the substrate to a deposition temperature may comprise heating the substrate to a temperature between about 20° C. and about 500° C., less than 475° C., than 450° C., between about 150° C. and 450° C., between about 150° C. and 425° C., or between about 175° C. and 400° C. or between about 300° C. and 350° C. In some cases, a temperature is controlled at a relatively high temperature (e.g., greater than 310° C.), such that deposition of the metal hardmask during step 104 results in deposition of material with relatively high (e.g., greater than 0.16 GPa or 2.1 GPa) tensile stress. The relatively high temperature (e.g., greater than 310° C.) is thought to facilitate volatizing and removal of byproducts during metal hardmask layer formation.

In addition to controlling the temperature of the substrate, a pressure within the reaction chamber may also be regulated. For example, in some embodiments of the disclosure, the pressure within the reaction chamber during step 102 and/or at a beginning of step 104 may be less than 1500 Pa or between about 200 and about 1000 Pa, or about 250 and about 750 Pa.

During step 104, a metal hardmask layer is formed on the substrate. In accordance with examples of the disclosure, step 104 is a cyclical deposition process that includes repeating a cycle comprising: supplying a metal-containing precursor to the substrate, supplying a reactant to the substrate, and applying a power to the reactor to activate the reactant to react with the metal-containing precursor or derivative thereof on the substrate to form the metal hardmask. In accordance with examples of the disclosure, the metal hardmask layer is or includes one or more of a metal nitride, a metal carbide, and a metal carbonitride. As discussed in more detail below, various properties of the metal hardmask layer can be tuned (e.g., to obtain relatively high tensile strength and/or low crystallinity) to mitigate line wiggling and/or line edge roughness in features that might otherwise occur-particularly in structures that include a line pitch of 28 nm or less. Additional properties that can be tuned include etch rate and etch selectivity relative to underlying layers.

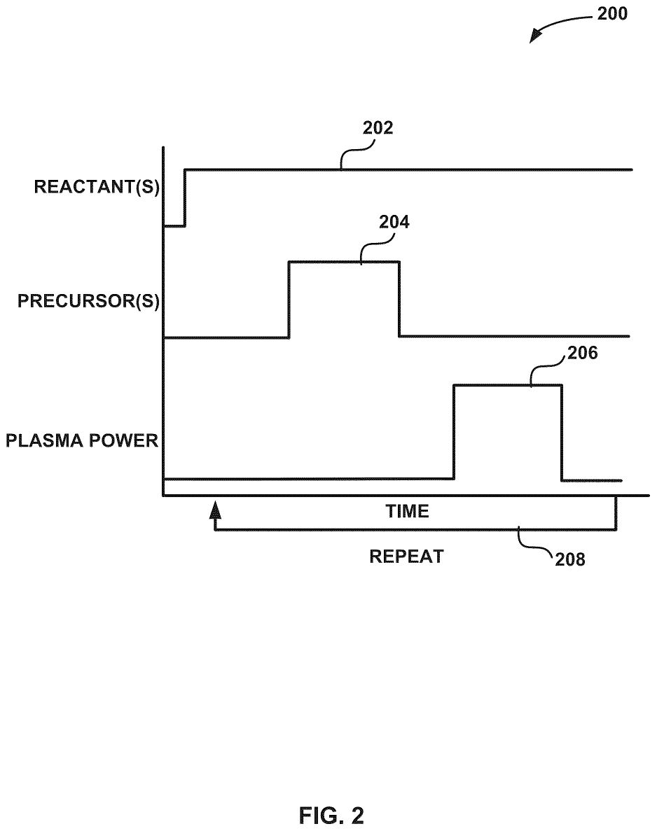

FIG. 2 illustrates an exemplary timing sequence 200 or a cycle suitable for use with step 104. In the illustrated example, timing sequence 200 includes a step of providing one or more reactants (step 202), a step of providing one or more precursors (step 204), and a step of applying a power to the reactor (step 206). As illustrated, the cycle can be repeated (step 208).

During step 202, one or more reactants are provided to a reaction space within the reactor. The reactant can be or include, for example, an inert gas, a hydrogen-containing gas, and/or a nitrogen-containing gas. The inert gas can be or include, for example, one or more of argon and helium. The nitrogen-containing gas can include one or more of nitrogen (N₂), NH₃, or N₂H₂. The hydrogen-containing gas can include one or more of hydrogen (H₂), H₂O, or H₂O₂. A reactant comprising hydrogen and nitrogen can include a mixture of hydrogen and nitrogen, ammonia, hydrazine, an alkyl substituted hydrazine, or the like. In some cases, the reactant can include argon and a hydrogen-containing gas (e.g., hydrogen) to form the metal carbide. In some cases, the reactant can include hydrogen and nitrogen (e.g., a nitrogen-containing and/or a hydrogen-containing gas) to form the metal nitride. In some cases, the reactant comprises hydrogen, nitrogen, and an inert gas (e.g., a nitrogen-containing and/or a hydrogen-containing gas and argon) to form the metal carbonitride. In some cases, a ratio of a flowrate of the hydrogen-containing gas (e.g., hydrogen), the nitrogen-containing gas (e.g., nitrogen), and the inert gas (e.g., argon) is about 1:1:2. In some cases, inclusion of nitrogen as a reactant is thought to improve properties of the deposited metal hardmask material.

A flowrate of one or more of (e.g., each of) the reactant(s) during step 202 can be between about 100 sccm and about 6000 sccm. A duration of step 202 can continue through one or more cycles.

During step 204, a metal precursor is provided (e.g., pulsed) to the reaction space within the reactor. In accordance with various embodiments of the disclosure, the precursor includes one or more of a molybdenum and a tungsten. In other words, the metal-containing precursor includes one or more of a molybdenum precursor and a tungsten precursor. In some cases, the metal-containing precursor includes the molybdenum-containing precursor and the tungsten-containing precursor. In these cases, the molybdenum-containing precursor and the tungsten-containing precursor can be supplied to the reaction space/substrate concurrently or alternatingly and sequentially. A ratio of flowrates of the molybdenum precursor to the tungsten precursor can be from about 1 to 10 or about 1 to 1.

In accordance with various examples of the disclosure, the metal-containing precursor is or includes a compound having one or more ═NR groups, where each R is independently selected from a C2-C6 linear or branched alkane. In accordance with additional examples, the metal containing precursor is or includes a compound having one or more-NRx groups, where each R is independently selected from a C1-C4 linear or branched alkane and where x is from 1 to 3. By way of particular examples, the metal-containing precursor can be or include one or more of bis(tert-butylimido)bis(dimethylamino)molybdenum [(^{t}BuN)₂(NMe₂)₂Mo], bis(tert-butylimino)bis(dimethylamino)tungsten [((CH₃)₃CN)₂W(N(CH₃)₂)₂], or dicarbonyl [(1,2,3,4,5-η)-1-methyl-2,4-cyclopentadien-1-yl]nitrosyl molybdenum [CH₃C₅H₄Mo(CO)₂NO].

A flowrate of the precursor to the reaction space can be between about 10 and about 1000 sccm. A duration of step/pulse 204 can be between about 0.1 and about 30 seconds.

During step 206, a power is applied to the reactor to activate the reactant to react with the metal-containing precursor or derivative thereof on the substrate to form the metal hardmask. The power can be applied to, for example, a gas distribution device, such as a showerhead assembly. In some cases, an opposing electrode, such as a susceptor, is grounded. The power that is applied during step 206 can have an intensity of between about 200 W and about 800 W or between about 100 and about 1000 W. A duration of step 206 can be between greater than 4 seconds or between about 0.1 and about 30 seconds to, for example, obtain a desired tensile stress in the deposited metal hardmask material.

The reactor can be purged after step 204 and/or 206 using the reactant(s) and/or one or more inert gases. A vacuum source can also be used to facilitate the purge.

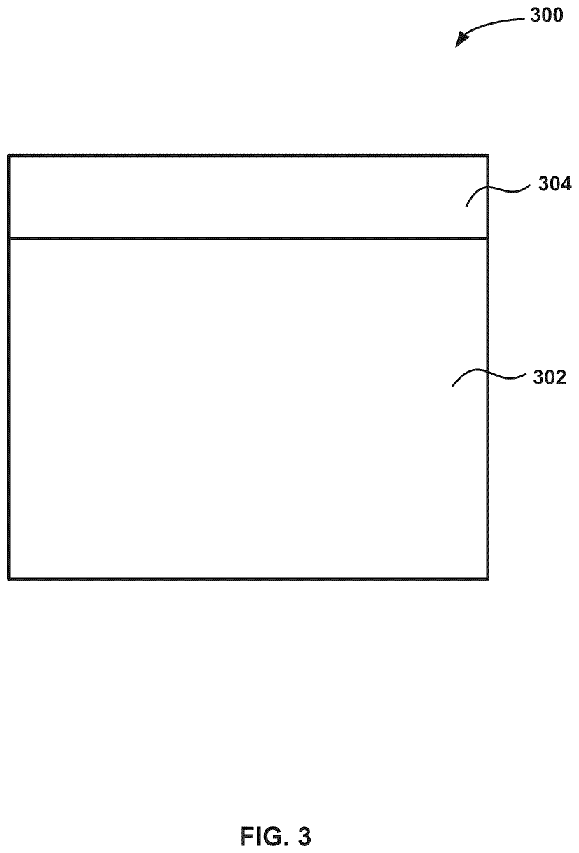

FIG. 3 illustrates a structure 300 that can be formed using method 100. In the illustrated example, structure 300 includes a substrate 302 and a metal hardmask layer 304. The metal hardmask layer 304 is deposited on substrate 302 using method 100. The metal hardmask layer 304 can be or include, for example, one or more of molybdenum nitride (MoN), molybdenum carbide (MoC), molybdenum carbonitride (MoCN), tungsten nitride (WN), tungsten carbide (WC), tungsten carbonitride (WCN), and tungsten molybdenum carbo nitride (WMoCN).

In accordance with aspects of these embodiments, a tensile stress of the metal hardmask layer is greater than 2.1 GPA, between about 200 MPa and about 2,000 MPa or between about 100 MPa and about 2500 MPa. Additionally or alternatively, a profile roughness (Rq) of the metal hardmask layer is about 0.3 nm or less—e.g., between about 0.1 and about 0.3 nm. Additionally or alternatively, a dielectric constant of the metal hardmask layer is about 3.0 or less.

When the metal hardmask layer 304 includes a metal nitride, such as MON or WN, it was observed that adding nitrogen to a plasma gas during deposition increased nitrogen concentration in the metal hardmask layer, varied a carbon concentration in the metal hardmask layer, and decreased oxygen concentration in the metal hardmask layer. Table 1 below illustrates exemplary process conditions and corresponding tensile stress in the metal hardmask layer 304.

TABLE 1

| | Condition 1 | Condition 2 | Condition 3 |
|---|---|---|---|
| Process parameters | (MoC film) | (MoC film) | (MoCN film) |
| Temperature(° C.) | 300/200/150 | 250/200/150 | 320/200/150 |
| (susceptor/showerhead/ | | | |
| reactor wall) | | | |
| RF power (Watt) | 200 to300 | 200 to 250 | 200 to 250 |
| Plasma frequency (MHz) | 10 to 30 | 10 to 30 | 10 to 30 |
| Pressure (Pa) | 300 to 400 | 500 to 700 | 500 to 700 |
| H₂ (slm) | 0.2to 0.5 | 0.3 to 0.8 | 0.3 to 0.8 |
| N₂ (slm) | — | — | 0.3 to 0.8 |
| Ar (slm) | 1.0 to 2.0 | 1.0 to 2.0 | 1.0 to 2.0 |
| RF on time (second) | 0.5 to 1.5 | 1.0 to 3.0 | 2.0 to 6.0 |
| Precursor feed time | 0.2 to 0.5 | 0.2 to 0.5 | 0.2 to 0.5 |
| (second) | | | |
| Cycle | 624 | 629 | 367 |
| Film thickness (nm) | 20.33 | 20.66 | 21.06 |
| Film growth rate per | 0.32 | 0.32 | 0.57 |
| cycle (Å/cycle) | | | |
| Dielectric constant (k) | 1.97 | 2.17 | 2.64 |
| Process time (minutes) | 20 | 30.93 | 30.28 |
| Stress (MPa) | 164.8 | 619.9 | 2121.9 |

The metal hardmask layer 304 can include organic carbon. The organic carbon in the film can correspond to byproducts or unreacted precursor molecules, whereas carbon in the form of MoC indicates direct bonding of carbon with Mo.

The organic C % in the metal hardmask layer 304 is reduced or can be reduced by three important factors, viz., (i) high temperature, (ii) longer RF on time and (iii) appropriate ratio of H₂:N₂:Ar in the process. Exemplary process conditions are provided above.

As mentioned above, byproducts and unreacted precursors are volatized and removed at high temperature, longer RF on time supports for more chemical reaction, N₂ plasma in the deposition cycle improves the conversion of precursor to a metal nitride film (e.g., MoN) and the hydrogen-containing gas (e.g., H₂) and the inert gas (e.g., Ar) plasma support removal of the byproducts and any unreacted reactants.

In some cases, the organic carbon in metal hardmask layer 304 corresponds to —CH, C═O, O—C═O bonding in the film, i.e., methyl and butyl groups in the precursor can react with oxygen on the wafer (native oxide or some impurities on the wafer surface) in the presence of H₂ plasma, and also the precursor molecules can remain in the film as unreacted.

The reason for how organic carbon drives compressive stress is the reduction/shrinkage of large intermolecular spaces of organic compounds or porous structure (under high temperature, low pressure longer RF on time and HRF power), which reduces their volume and compresses the film. As a result, the film exhibits relatively high compressive stress.

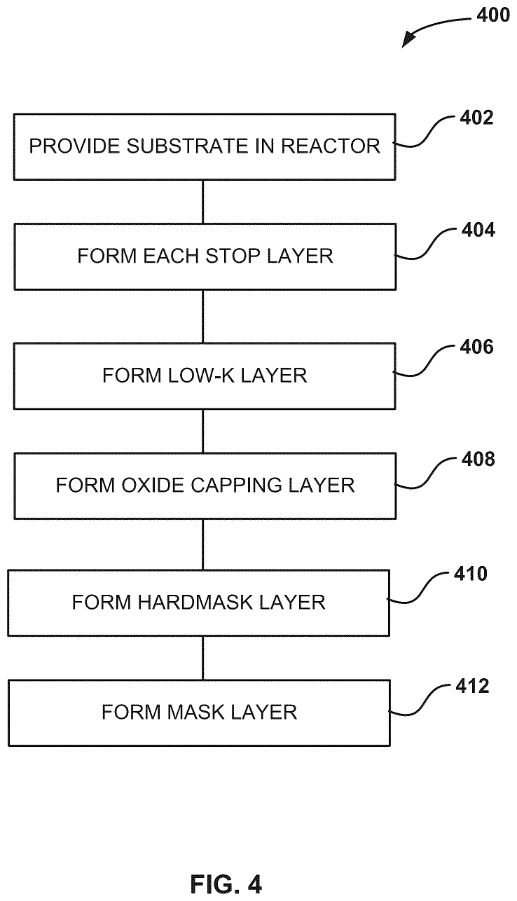

FIG. 4 illustrates another method 400 in accordance with examples of the disclosure. Method 400 includes providing a substrate in a reactor (step 402), forming an etch stop layer on the substrate (step 404), forming a low-k layer on the etch stop layer (step 406), forming an oxide capping layer on the low-k layer (step 408), forming a metal hardmask layer on the capping layer (step 410), and forming a mask layer (step 412). As above, the metal hardmask layer can be or include one or more of a metal nitride, a metal carbide, and a metal carbonitride.

During step 402, a suitable substrate is provided. The substrate can be as described above. The reactor can also be as described above. Steps of method 400 can suitably be performed in one or more reactors, which can be part of a cluster tool.

During step 404, an etch stop layer is formed on the substrate. The etch stop layer can be or include, for example, silicon nitride, SiN, or the like. The etch stop layer can be formed using, for example, PECVD or ALD.

During step 406, a low-k layer is formed (e.g., directly) on the etch stop layer. The low-k layer can be or include, for example, SiOCH or SiOC. The low-k layer can be formed using, for example, PECVD or ALD.

During step 408, an oxide capping layer is formed (e.g., directly) on the low-k layer. The oxide capping layer can be or include, for example, silicon oxide, or the like. The oxide capping layer can be formed using, for example, PECVD or ALD.

During step 410, a metal hardmask layer is formed (e.g., directly) on the oxide capping layer. Step 410 can be the same or similar to method 100 described above. The metal hardmask material can be as described above in connection with FIG. 3.

During step 412, a mask layer is formed (e.g., directly) on the metal hardmask layer. The mask layer can be applied using, for example, spin-on coating or gas-phase processes. The mask material can be or include photoresist material, such as EUV photoresist material.

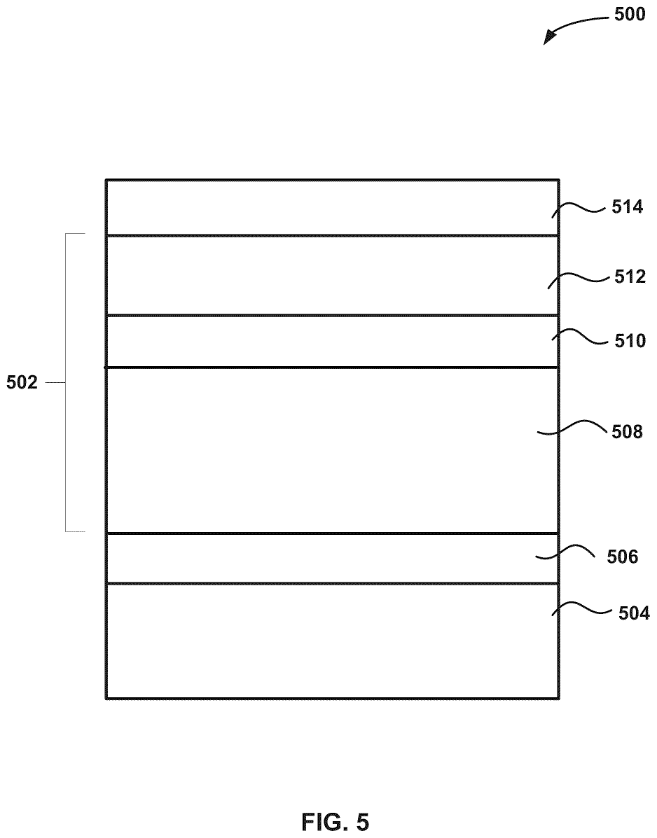

FIG. 5 illustrates a structure 500 including a layer stack 502 on a substrate 504 having an etch stop layer 506 thereon. Substrate 504 can be or include a substrate as described herein. Etch stop layer 506 can be as described above. A thickness of the etch stop layer can be between about 1 and about 5 nm.

Layer stack 502 includes a low-k layer 508, an oxide capping layer 510 on low-k layer, and a metal hardmask layer 512 on oxide capping layer. Structure 500 also includes a mask layer 514 overlying metal hardmask layer 512. Low-k layer 508, oxide capping layer 510, and metal hardmask layer 512 can be as described above. A thickness of low-k layer 508 can be between about 100 and about 200 nm. A thickness of oxide capping layer 510 can be between about 1 and about 5 nm. A thickness of metal hardmask layer 512 can be between about 5 and about 20 nm.

Although not separately illustrated, method 400 can additionally include patterning the mask layer (e.g., by masking and developing the mask layer) and/or etching a portion of the layer stack (e.g., a portion of the low-k layer, the oxide capping layer, and the metal hardmask layer) to form a recess. The etching can include multiple etch steps, such as plasma dry etch and CMP. The method can further include filling the recess with conductive material, such as copper. The conductive material (e.g., copper) can be deposited using, for example, PVD.

Exemplary methods can also include etching a low-k layer underlying the metal hardmask layer. The low-k layer can be etched using, for example, argon/C₄F₈/oxygen plasma. During a low-k layer etch, the metal hardmask layer can become more compressive. To compensate for this, the metal hardmask layer desirably has an initial tensile stress that is relatively high, such as a tensile stress noted herein.

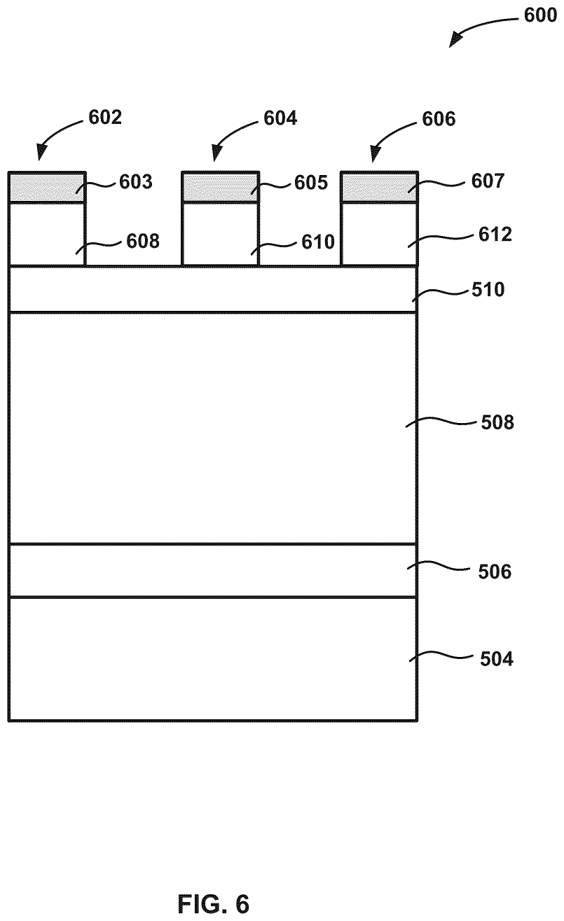

FIG. 6 illustrates a structure 600 after patterning mask layer 514 and metal hardmask layer 512 to form features 602, 604, 606 that include pattern mask material 603, 605, 607 and metal hardmask material features 608, 610, 612. The metal hardmask layer 512 can be etched using, for example, Cl₂/argon plasma.

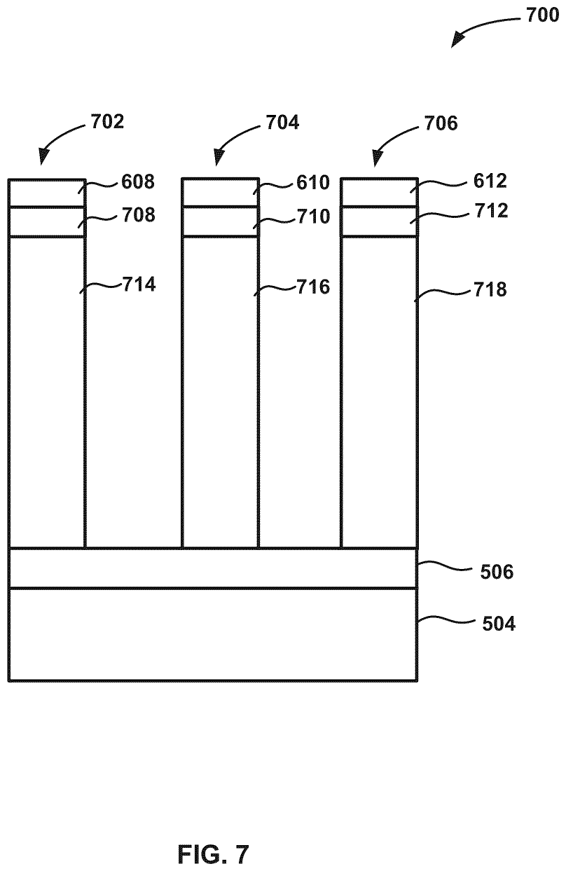

After the metal hardmask etch, the mask layer 602, 604, 606 can be removed, and metal hardmask features 608, 610, 612 can be used to pattern low-k layer 508 and oxide capping layer 510 to form features 702, 704, 706, illustrated in FIG. 7. Features 702-706 include hardmask material 608, 610, 612, oxide capping layer material 708, 710, 712, and low-k material 714, 716, 718.

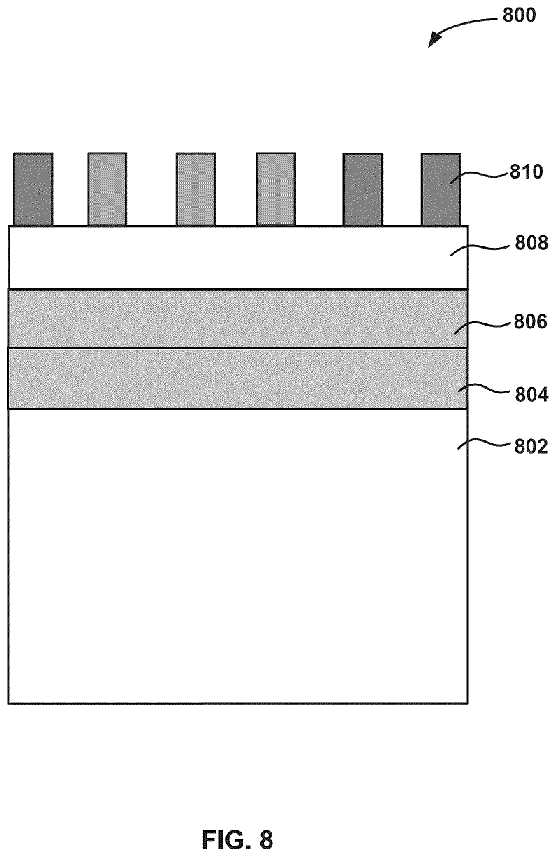

FIG. 8 illustrates another structure 800 in accordance with examples of the disclosure. The structure 800 includes a substrate 802, an etch stop layer 804, a silicon oxide layer 806, a metal hardmask layer 808, and patterned features 810. Substrate 802 and etch stop layer 804 can be the same or similar to substrate 504 and etch stop layer 506 respectively described above. The silicon oxide layer 806 can be formed using, for example PECVD or ALD. A thickness of the silicon oxide layer 806 can be between about 1 and about 3 nm. The patterned features 810 can be formed by exposing and developing a mask layer, such as mask layer 514 described above.

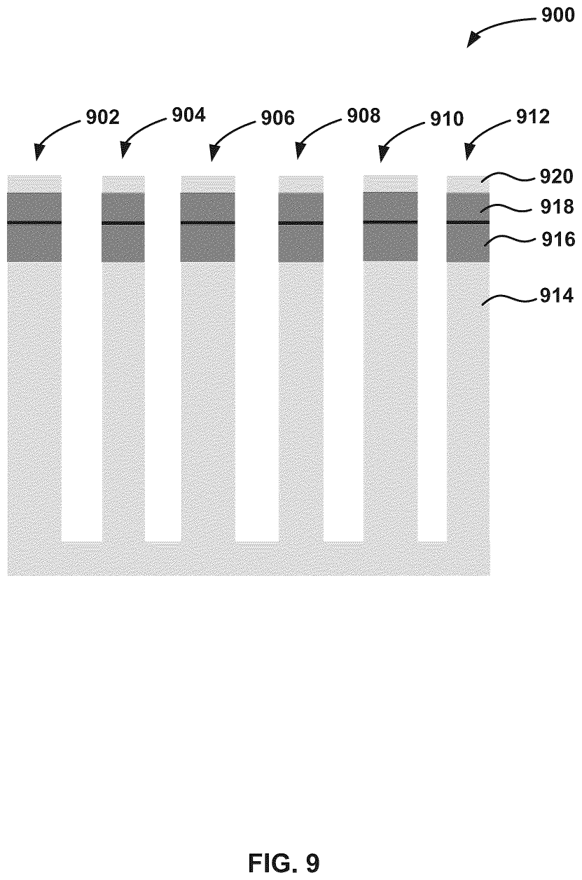

FIG. 9 illustrates a structure 900 after patterning of metal hardmask layer 808 (e.g., as described above) and etching of silicon oxide layer 806, etching of etch stop layer 804, removal of patterned features 810 (e.g., using an ashing process), and etching of substrate 802 to form features 902, 904, 906, 908, 910, 912. The silicon oxide layer 806 can be etched using, for example, argon/CF₄/CHₓF_{y}/oxygen plasma. The etch stop layer 804 can be etched using, for example, argon/CF₄/CHₓF_{y}/oxygen plasma. The features 902-912 include a substrate material 914 (e.g., silicon), an etch stop material 916 (e.g., silicon nitride), a silicon oxide material 918, and a metal hardmask material 920.

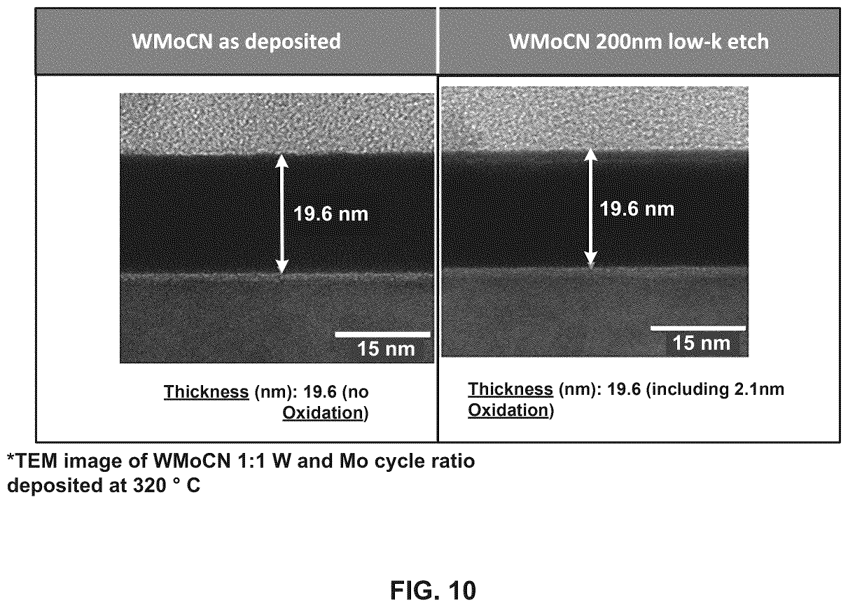

FIG. 10 illustrates transmission electron microscopy micrographs of WMoCN metal hardmask layers as deposited and after etching a low-k material. The micrographs illustrate that some oxidation of the WMoCN surface occurs after etching the low-k material.

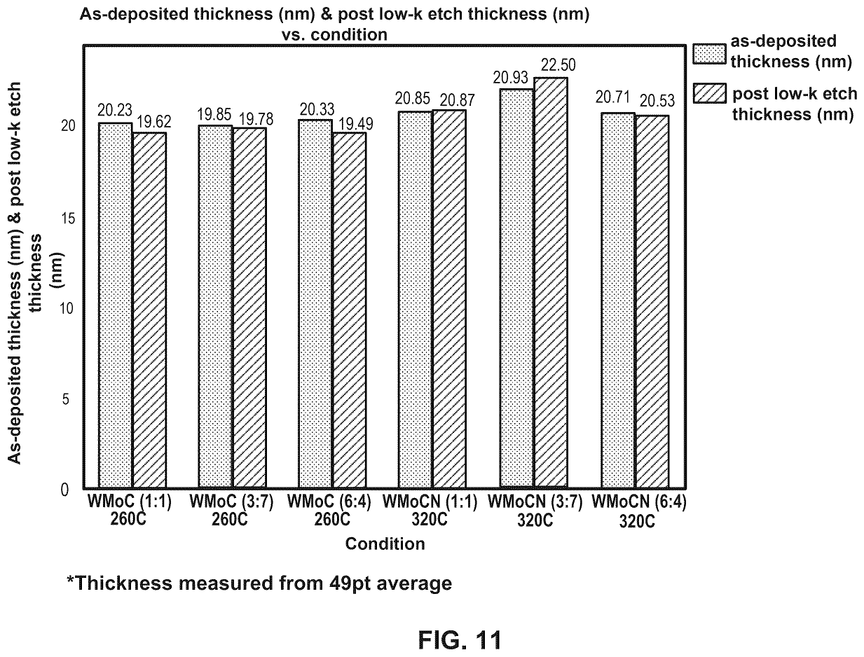

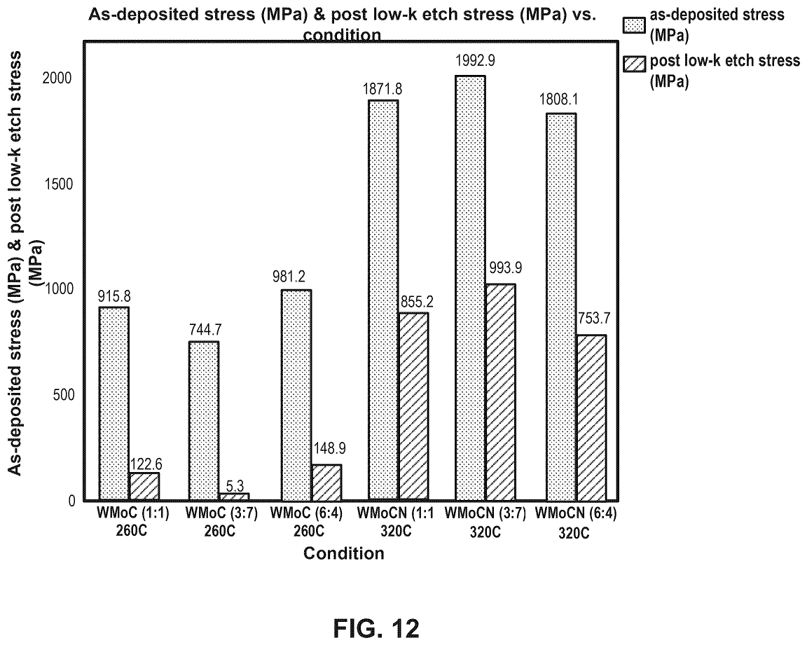

FIGS. 11 and 12 illustrate examples where the metal in the metal hardmask layer is tungsten (e.g., the layer is WN or WCN). In particular, FIG. 11 illustrates as-deposited thickness of the metal hardmask and a thickness of the metal hardmask layer after etching a low-k material at various conditions. As illustrated, the thickness of the metal hardmask material does not vary significantly. FIG. 12 illustrates tensile stress in the metal hardmask layer as deposited and after etching a low-k material.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

1. A method of forming a structure comprising a metal hardmask layer on a substrate, the method comprising:
providing a substrate in a reactor; and
forming a metal hardmask layer on the substrate by repeating a cycle comprising:
supplying a metal-containing precursor to the substrate;
supplying a reactant to the substrate; and
applying a power to the reactor to activate the reactant to react with the metal-containing precursor or derivative thereof on the substrate to form the metal hardmask,
wherein the metal hardmask layer comprises one or more of a metal nitride, a metal carbide, and a metal carbonitride.

2. The method of claim 1, wherein the metal-containing precursor comprises one or more of a molybdenum and a tungsten.

3. The method of claim 1, wherein the metal-containing precursor comprises a compound having one or more ═NR groups, where each R is independently selected from a C2-C6 linear or branched alkane.

4. The method of claim 1, wherein the metal containing precursor comprises a compound having one or more-NRx groups, where each R is independently selected from a C1-C4 linear or branched alkane and where x is from 1 to 3.

5. The method of claim 2, wherein the metal-containing precursor comprises one or more of bis(tert-butylimido)bis(dimethylamino)molybdenum [(^{t}BuN)₂(NMe₂)₂Mo], bis(tert-butylimino)bis(dimethylamino)tungsten [((CH₃)₃CN)₂W(N(CH₃)₂)₂], or dicarbonyl [(1,2,3,4,5-η)-1-methyl-2,4-cyclopentadien-1-yl]nitrosyl molybdenum [CH₃C₅H₄Mo(CO)₂NO].

6. The method of claim 2, wherein the metal-containing precursor comprises the molybdenum-containing precursor and the tungsten-containing precursor, wherein the molybdenum-containing precursor and the tungsten-containing precursor are supplied to the substrate concurrently.

7. The method of claim 2, wherein the metal-containing precursor comprises the molybdenum-containing precursor and the tungsten-containing precursor, wherein the molybdenum-containing precursor and the tungsten-containing precursor are supplied to the substrate alternatingly and sequentially.

8. The method of claim 1, wherein the reactant comprises argon and hydrogen-containing gas to form the metal carbide.

9. The method of claim 1, wherein the reactant comprises hydrogen-containing gas and nitrogen-containing gas to form the metal nitride.

10. The method of claim 1, wherein the reactant comprises hydrogen-containing gas, nitrogen-containing gas, and argon to form the metal carbonitride.

11. The method of claim 10, wherein a ratio of a flowrate of the hydrogen-containing gas, the nitrogen-containing gas, and the argon is about 1:1:2.

12. The method of claim 1, wherein a tensile stress of the metal hardmask layer is between about 200 MPa and about 2,000 MPa.

13. The method of claim 1, wherein a profile roughness (Rq) of the metal hardmask layer is about 0.3 nm or less.

14. The method of claim 1, wherein the method is performed at a temperature of between about 150° C. and about 450° C.

15. The method of claim 1, wherein the power is applied at an intensity of between about 200 W and about 800 W.

16. The method of claim 1, wherein the method is performed at a pressure of between about 200 Pa and about 1,000 Pa.

17. The method of claim 1, wherein a dielectric constant of the metal hardmask layer is about 3.0 or less.

18. A method of forming a layer stack on a substrate comprising:
providing a substrate in a reactor;
forming an etch stop layer on the substrate;
forming a low-k layer on the etch stop layer;
forming an oxide capping layer on the low-k layer;
forming a metal hardmask layer on the oxide capping layer; and
forming a mask layer,
wherein the metal hardmask layer comprises one or more of a metal nitride, a metal carbide, and a metal carbonitride.

19. The method of claim 18, further comprising etching a portion of the layer stack to form a recess therein, followed by filling the recess with copper.

20. The method of claim 18, wherein the metal hardmask layer comprises one or more of molybdenum nitride (MoN), molybdenum carbide (MoC), molybdenum carbonitride (MoCN), tungsten nitride (WN), tungsten carbide (WC), tungsten carbonitride (WCN), and tungsten molybdenum carbo nitride (WMoCN).
